(19) United States
(12) Patent Application Publication
(10) Pub. No.: US 2013/0221519 A1
(43) Pub. Date: Aug. 29, 2013

(54) SEMICONDUCTOR DEVICES INCLUDING DUMMY SOLDER BUMPS

(71) Applicant: Samsung Electronics Co., Ltd., (US)

(72) Inventors: Son-kwan Hwang, Suwon-si (KR); Byung-Iyul Park, Seoul (KR); Hyun-soo Chung, Hwasung-si (KR); Jin-ho Chun, Seoul (KR); Gil-heyun Choi, Seoul (KR)

(73) Assignee: Samsung Electronics Co., Ltd., Suwon-si (KR)

(21) Appl. No.: 13/753,774

(22) Filed: Jan. 30, 2013

(30) Foreign Application Priority Data
Feb. 23, 2012 (KR) 10-2012-0018652

(51) Int. Cl. H01L 23/498

(52) U.S. Cl. CPC H01L 23/49811
USPC 257/737

(57) ABSTRACT

A semiconductor device includes a substrate on which integrated circuit units are formed, main solder bumps that are electrically connected to the integrated circuit units on the substrate and dummy solder bumps that are not electrically connected to the integrated circuit units on the substrate. The dummy solder bumps are narrower than wiring patterns immediately below the dummy solder bumps.

### CROSS-REFERENCE TO RELATED APPLICATION

This application claims the benefit of Korean Patent Application No. 10-2012-0018652, filed on Feb. 23, 2012, in the Korean Intellectual Property Office, the disclosure of which is incorporated herein in its entirety by reference.

### BACKGROUND

Various embodiments described herein relate to semiconductor devices, and more particularly, to semiconductor devices having dummy solder bumps.

A semiconductor device extends an internal circuit function to an external electronic device through pads, which are connected to an external printed circuit board or other substrate. As the miniaturization and integration density of semiconductor devices continues and the operational speeds increase, there is an increasing use of connecting an internal circuit to a printed circuit board through solder bumps.

### SUMMARY

Various embodiments described herein can provide semiconductor devices including a substrate, a plurality of integrated circuit units on the substrate and a plurality of main solder bumps that are electrically connected to the integrated circuit units on the substrate. A plurality of dummy solder bumps are also provided that are not electrically connected to the integrated circuit units on the substrate. The dummy solder bumps are narrower than wiring patterns directly therebelow.

The dummy solder bumps each may have a flat bottom.

Each of the dummy solder bumps may include a pillar adjacent the substrate and a reflow solder layer remote from the substrate. Sidewalls of the pillar may have a vertical profile.

The dummy solder bumps may perpendicularly overlap with the wiring patterns.

The semiconductor device may further include an insulating interlayer on the integrated circuit units and a plurality of pads on the insulating interlayer. The wiring patterns are in the insulating interlayer.

The semiconductor device may further include a passivation layer on the insulating interlayer to cover a portion of the pads and the wiring patterns.

The passivation layer may completely cover the wiring patterns and the dummy solder bumps may be on the passivation layer.

Portions of an outer surface of the passivation layer on which the dummy solder bumps are located may be flat.

The passivation layer may expose a portion of the pads and a portion of the wiring patterns. The main solder bumps may be on the exposed portion of the pads and the dummy solder bumps may be on the exposed portion of the wiring patterns.

Outer surfaces of the wiring patterns on which the dummy solder bumps are located may be flat.

Each of the wiring patterns may include two closely spaced apart wiring lines.

According to various other embodiments described herein, there is provided a semiconductor device including a substrate, a plurality of integrated circuit units on the substrate and an insulating interlayer on the integrated circuit units on the substrate. A plurality of wiring patterns and pads are provided on the insulating interlayer and are electrically connected to the integrated circuit units. A passivation layer is on the wiring patterns and the pads on the insulating interlayer. A plurality of main solder bumps are electrically connected to the integrated circuit units through the pads. A plurality of dummy solder bumps are on the passivation layer immediately below which the wiring patterns are not present.

The dummy solder bumps may have a flat bottom.

Sidewalls of the dummy solder bumps may have a vertical profile.

The passivation layer under the dummy solder bumps may be more planar than the passivation layer on the wiring patterns.

A semiconductor device according to various other embodiments described herein includes a substrate and a plurality of semiconductor integrated circuit units on the substrate. A plurality of main solder bumps are provided on the semiconductor integrated circuit units, remote from the substrate, that are electrically connected to circuits in the semiconductor integrated circuit units. A plurality of dummy solder bumps are provided on the semiconductor integrated circuit units, remote from the substrate, that are mechanically connected to the semiconductor integrated circuit units but are not electrically connected to the circuits in the semiconductor integrated circuit units. A respective dummy solder bump has a floor that is adjacent the semiconductor integrated circuit units and a sidewall that meets the floor at a right angle.

In some embodiments, the semiconductor device further comprises a wiring pattern between the semiconductor integrated circuit units and the main and dummy solder bumps, wherein the floor is narrower than the wiring pattern that is adjacent thereto. Moreover, in other embodiments, the sidewall defines an enclosed area and the floor is flat throughout the enclosed area.

In some embodiments, the substrate includes a plurality of pads thereon that are electrically connected to the plurality of main solder bumps. The dummy solder bumps are not electrically connected to a pad on the substrate. Moreover, a passivation layer may also be provided on the substrate. The passivation layer includes apertures therein that expose the plurality of pads and has a flat outer surface adjacent the dummy solder bumps.

### BRIEF DESCRIPTION OF THE DRAWINGS

Various embodiments described herein will be more clearly understood from the following detailed description taken in conjunction with the accompanying drawings in which:

FIG. 1 is a cross-sectional view of a semiconductor device package having a semiconductor device according to various embodiments described herein;

FIG. 2 is a plan view of the semiconductor device of FIG. 1;

FIG. 3 is a cross-sectional view of a semiconductor device according to various embodiments described herein;

FIG. 4 is a cross-sectional view of a semiconductor device according to various embodiments described herein;

FIG. 5 is a cross-sectional view of a semiconductor device according to various embodiments described herein;

FIG. 6 is a cross-sectional view of a semiconductor device according to various embodiments described herein;

FIG. 7 is a cross-sectional view of a semiconductor device according to various embodiments described herein; and

FIGS. 8A through 8I are cross-sectional views for explaining a method of manufacturing a semiconductor device, according to various embodiments described herein.

FIG. 9 is a block diagram illustrating an example of an electronic device including a semiconductor device according to various embodiments described herein.

### DETAILED DESCRIPTION OF THE EMBODIMENTS

Hereafter, the inventive concepts will be described more fully with reference to the accompanying drawings, in which various embodiments are shown. The inventive concepts may, however, be embodied in many different forms and should not be construed as limited to the various embodiments set forth herein. Rather, these embodiments are provided so that this disclosure will be thorough and complete, and will fully convey the scope of the invention to those of ordinary skill in the art. In the drawings, lengths and sizes of layers and regions may be exaggerated for clarity.

It will be understood that when an element or layer is referred to as being “on”, “connected to,” or “coupled to” another element or layer, it can be directly on, connected to or coupled to another element or layer or intervening elements or layers may be present. In contrast, when an element is referred to as being “directly on”, “directly connected to” or “directly coupled to” another element or layer, there are no intervening elements or layers present. Like numbers refer to like elements throughout. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concepts.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes may be not intended to illustrate the actual shape of a region of a device and are not intended to limit the scope of exemplary embodiments.

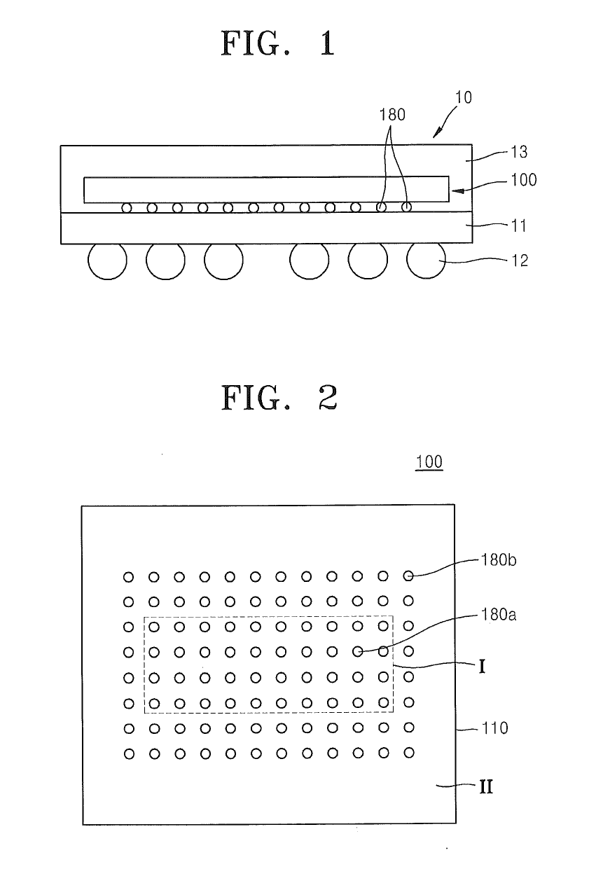

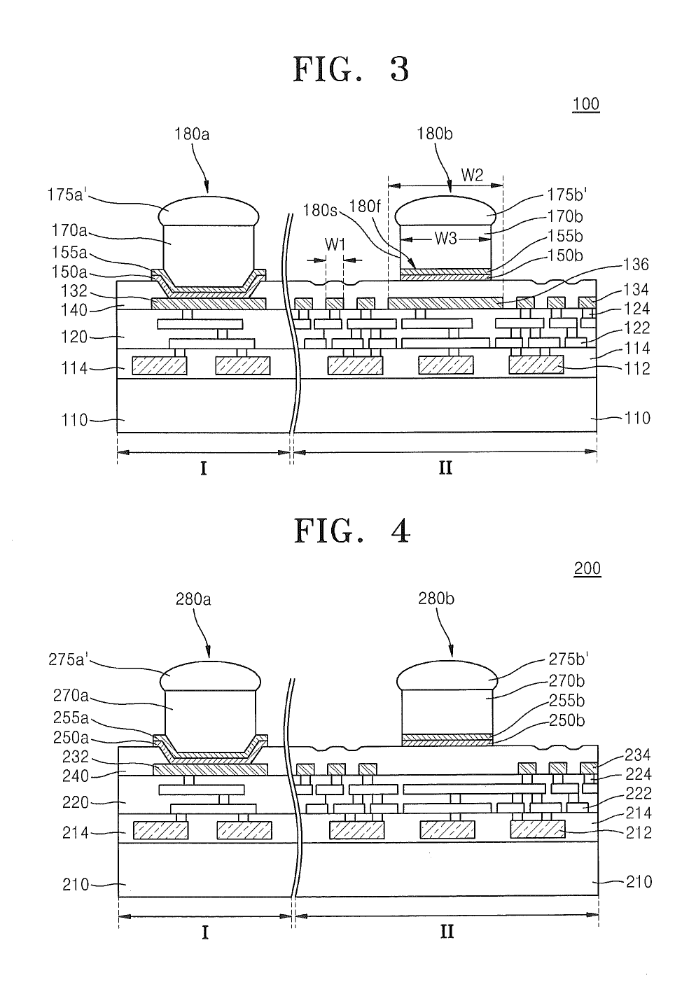

FIG. 1 is a cross-sectional view of a semiconductor device package 10 including a semiconductor device 100, according to various embodiments described herein. FIG. 2 is a bottom view of the semiconductor device 100 of FIG. 1.

Referring to FIGS. 1 and 2, the semiconductor device package 10 includes the semiconductor device 100 connected to a printed circuit board (PCB) or other mounting substrate 11, solder bumps 12, and a sealing member 13.

The semiconductor device 100 includes a substrate 110 on which an integrated circuit unit (not shown) is provided, and a plurality of solder bumps 180 including main solder bumps 180a and dummy solder bumps 180b on the substrate 110. The semiconductor device 100 is connected to the PCB 11 through the main solder bumps 180a and the dummy solder bumps 180b.

The integrated circuit unit may include devices that function as memories, logic, microprocessors, analog devices, digital signal processors, system-on chips. The integrated circuit unit may be provided as a separate semiconductor die or as a portion of a common semiconductor die. In FIG. 1, one semiconductor device 100 is depicted. However, the semiconductor device package 10 may have a structure in which a plurality of semiconductor devices 100 are stacked. For example, the semiconductor device 100 may include at least two memory devices, and the semiconductor device 100 may include both a micro-controller and at least one memory device.

The main solder bumps 180a may be arranged in a matrix in a predetermined region (defined as a main solder bump formation region I) of a lower surface of the substrate 110. In FIG. 2, as an example, the main solder bumps 180a are arranged on a central region of the substrate 110. However, the region of the main solder bumps 180a is not limited thereto. The main solder bumps 180a may provide input/output signals between the semiconductor device 100 and the PCB 11.

The dummy solder bumps 180b may be arranged in various forms on a predetermined region (defined as a dummy solder bump formation region II) of a lower surface of the substrate 110. The dummy solder bumps 180b may have a height and a width similar to those of the main solder bumps 180a. In FIG. 2, as an example, the main solder bumps 180a are arranged on a central region of the substrate 110, and the dummy solder bumps 180b are arranged to surround the main solder bumps 180a. In other embodiments, the main solder bumps 180a and the dummy solder bumps 180b may be arranged in a matrix on edges of the substrate 110. The dummy solder bumps 180b do not provide an electrical connection between the semiconductor device 100 and the PCB 11.

If the semiconductor device package 10 has a structure in which a plurality of semiconductor devices 100 are stacked, the semiconductor device package 10 may include a plurality of stacks formed by stacking a plurality of substrates 110 through which through silicon vias (TSVs) (not shown) are formed. The main solder bumps 180a and the dummy solder bumps 180b may be provided between the plurality of substrates 110. The main solder bumps 180a may be connected to the TSVs to provide input/output signals to an integrated circuit unit, such as transistors and memory devices which are on the stack.

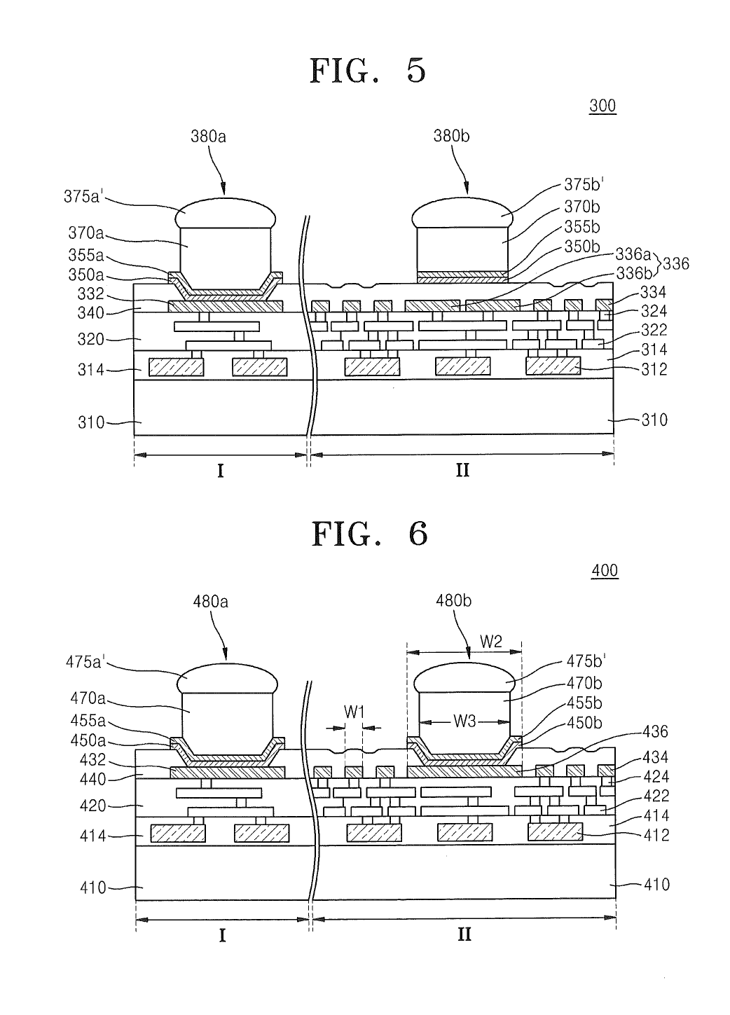

FIG. 3 is a cross-sectional view of a semiconductor device 100 according to various embodiments described herein.

Referring to FIG. 3, the substrate 110 is divided into a main solder bump formation region I and a dummy solder bump formation region II. Integrated circuit units 112, such as diodes, transistors, and memory devices, are provided on the substrate 110, and a first insulating interlayer 114 covers the integrated circuit units 112. Internal wiring patterns 122 and contact plugs 124 that are electrically connected to the integrated circuit units 112 are provided on the first insulating interlayer 114. A second insulating interlayer 120 that covers the internal wiring patterns 122 and the contact plugs 124 is provided on the first insulating interlayer 114. For example, a plurality of insulating layers (not shown) may be provided on the first insulating interlayer 114 and the insulating layers may cover the multi-layered internal wiring patterns 122 and the contact plugs 124. Accordingly, the insulating layers may be defined as the second insulating interlayer 120.

Pads 132 are provided on the second insulating interlayer 120 in the main solder bump formation region I. The pads 132 may be connected to the internal wiring patterns 122 and the contact plugs 124 within the second insulating interlayer 120 to be electrically connected to the integrated circuit units 112. The pads 132 may function as input/output pads that apply input/output signals to the integrated circuit units 112.

A first wiring pattern 134 and a second wiring pattern 136 are provided on the second insulating interlayer 120 in the dummy solder bump formation region II. The first wiring pattern 134 and the second wiring pattern 136 may be electrically connected to the integrated circuit units 112 located on the substrate 110 through the internal wiring patterns 122 and the contact plugs 124 which are located in the second insulating interlayer 120.

The first wiring pattern 134 is located on a portion of the second insulating interlayer 120 on which the dummy solder bumps 180b are not formed. The first wiring pattern 134 may be arranged in various patterns according to a type and design of the integrated circuit units 112. For example, the first wiring pattern 134 may have a first width W1, and may be arranged in a plurality of lines separated from each other.

The second wiring pattern 136 is provided on a portion of the second insulating interlayer 120 on which the dummy solder bumps 180b are provided. The second wiring pattern 136 may have a second width W2. The second width W2 may be greater than a third width W3 of second pillars 170b of the dummy solder bumps 180b. Also, the second width W2 may be equal to or greater than the third width W3 of the second pillars 170b of the dummy solder bumps 180b. The second width W2 may be greater than the first width W1 of the first wiring pattern 134. In example embodiments, the second width W2 of the second wiring pattern 136 may be a few to a few tens of microns. Accordingly, the dummy solder bumps 180b are narrower than the wiring pattern 136 immediately therebelow.

A passivation layer 140 that covers the pads 132, the first wiring pattern 134, and the second wiring pattern 136 is provided on the second insulating interlayer 120. The passivation layer 140 covers edge portions of the pads 132 and may expose upper surfaces of the pads 132. The passivation layer 140 completely covers the first wiring pattern 134 and the second wiring pattern 136, and thus, upper surfaces of the first wiring pattern 134 and the second wiring pattern 136 are not exposed. The passivation layer 140 may include silicon nitride and/or polyimide. A portion of the passivation layer 140 on the first wiring pattern 134 may have an uneven upper surface having step differences. A portion of the passivation layer 140 on the second wiring pattern 136 may have a flat upper surface in a relatively wide region. The first wiring pattern 134 may be arranged as a plurality of lines separated by predetermined gaps, which are buried in a process of forming the passivation layer 140. Accordingly, the passivation layer 140 on the lines of the first wiring pattern 134 may be higher than the height of the passivation layer 140 not located on the lines of the first wiring pattern 134. Thus, the portion of the passivation layer 140 on the first wiring pattern 134 may have an upper surface having step differences. However, the second wiring pattern 136 has a relatively wide width, and thus, the portion of the passivation layer 140 on the second wiring pattern 136 may have a relatively flat upper surface.

A first barrier layer 150a may be provided on the pads 132 and inner surfaces of the passivation layer 140. In example embodiments, the first barrier layer 150a may include Cr, Ni, Ti and/or TiW. The first barrier layer 150a may have a thickness in a range from about 500 Å to about 4,000 Å.

A second barrier layer 150b may be provided on the passivation layer 140 that is on the second wiring pattern 136. In some embodiments, the second barrier layer 150b may include Cr, Ti and/or TiW. The second barrier layer 150b may have a thickness in a range from about 500 Å to about 4,000 Å. Since the second width W2 of the second wiring pattern 136 is relatively large, the upper surface of the passivation layer 140 above the second wiring pattern 136 is relatively wide and flat without step differences. Accordingly, the second barrier layer 150b is also flat on the flat region of the passivation layer 140.

First and second seed layers 155a and 155b are provided on the first and second barrier layers 150a and 150b, respectively. The first and second seed layers 155a and 155b may include Co, Ni and/or Au.

The first and second barrier layers 150a and 150b respectively may prevent materials that constitute the first and second seed layers 155a and 155b from diffusing downwards.

A main solder bump 180a includes a first pillar 170a and a first reflow solder layer 175a′, which are sequentially stacked on the first seed layer 155a. In example embodiments, the first pillar 170a may include Cu, Ni, Au, and/or an alloy of these metals. The first reflow solder layer 175a′ may be an alloy of Sn and Ag or only Sn, and, if necessary, Cu, Pd, Bi and/or Sb may be included. A vertical cross-section of the first pillar 170a may have a circular shape or an oval shape. A portion of the first reflow solder layer 175a′ is arranged to protrude with respect to sidewalls of the first pillar 170a, and, for example, may have a hemispherical shape.

The dummy solder bump 180b includes the second pillar 170b and a second reflow solder layer 175b′, which are sequentially stacked on the second seed layer 155b. The second pillar 170b may have a width W3 that is smaller than the second width W2 of the second wiring pattern 136 below the second pillar 170b. Also, an entire surface of the second pillar 170b may vertically overlap with the second wiring pattern 136. In example embodiments, the second pillar 170b may include Cu, Ni, Au and/or an alloy of these metals. The second reflow solder layer 175b′ may be an alloy of Sn and Ag, and, if necessary, Cu, Pd, Bi and/or Sb may be included in the alloy.

The second pillar 170b is on the second barrier layer 150b and the second seed layer 155b which are relatively flat, and sidewalls of the second pillar 170b may have a vertical profile from an upper surface of the second seed layer 155b. That is, the second pillar 170b may have a uniform width across an entire height. In a process of forming the second pillar 170b, after forming an opening (not shown) by using a photoresist process, the opening is filled with a material for forming the second pillar 170b. When sidewalls of the opening have a vertical profile and have a uniform width across an entire height, the height of the second pillar 170b that is formed in the opening may be easily controlled, and thus, the second pillar 170b may have a uniform height. Accordingly, the second pillar 170b may have a uniform volume and height.

An upper surface of the dummy solder bump 180b may be substantially level with or at a lower level than an upper surface of the main solder bump 180a. If the height of the dummy solder bump 180b is similar to that of the main solder bump 180a, stress concentrated on the main solder bump 180a may be distributed. If the height of the dummy solder bump 180b is substantially higher than that of the main solder bump 180a, an electrical connection to the main solder bump 180a may be disconnected due to the dummy solder bump 180b. If the height of the dummy solder bump 180b is substantially smaller than that of the main solder bump 180a, a stress distribution effect may be reduced. Accordingly, when the dummy solder bump 180b has a height similar to that of the main solder bump 180a, the reliability of the semiconductor device 100 may be increased.

According to the example embodiments, the passivation layer 140 below the dummy solder bump 180b has less step differences than the passivation layer 140 on which the dummy solder bump 180b is not present, and thus, the sidewalls of the second pillar 170b of the dummy solder bump 180b may be vertically formed and the height of the dummy solder bump 180b may be uniform. Accordingly, the semiconductor device 100 may have a high reliability.

FIG. 3 also illustrates a semiconductor device according to other embodiments that includes a substrate 110 and a plurality of semiconductor integrated circuit units 112 on the substrate 110. A plurality of main solder bumps 180a are provided on the semiconductor integrated circuit units 112, remote from the substrate 110, that are electrically connected to circuits in the semiconductor integrated circuit units. A plurality of dummy solder bumps 180b are also provided on the semiconductor integrated circuit units 112, remote from the substrate 110, that are mechanically connected to the semiconductor integrated circuit units 112, but are not electrically connected to the circuits in the semiconductor integrated circuit units 112. Moreover, a respective dummy solder bump 180b includes a floor 180f that is adjacent the semiconductor integrated circuit units 112, and a sidewall 180s that meets the floor 180f at a right angle.

As also illustrated in FIG. 3, a wiring pattern 136 is provided between the semiconductor integrated circuit units 112 and the main and dummy solder bumps 180a and 180b, respectively. The floor 180f is narrower than the wiring pattern 136 that is adjacent thereto. As also illustrated in FIG. 3, the sidewall 180s defines an enclosed area and the floor 180f is flat throughout the enclosed area. As also illustrated in FIG. 3, the substrate 110 includes a plurality of pads 132 thereon that are electrically connected to the plurality of main solder bumps 180a, and the dummy solder bumps 180b are not electrically connected to a pad 132 on the substrate. Finally, FIG. 3 also illustrates various embodiments that comprise a passivation layer 140 on the substrate 110 that includes apertures therein that expose the plurality of pads 132, and that has a flat outer surface adjacent the dummy solder bumps 180b.

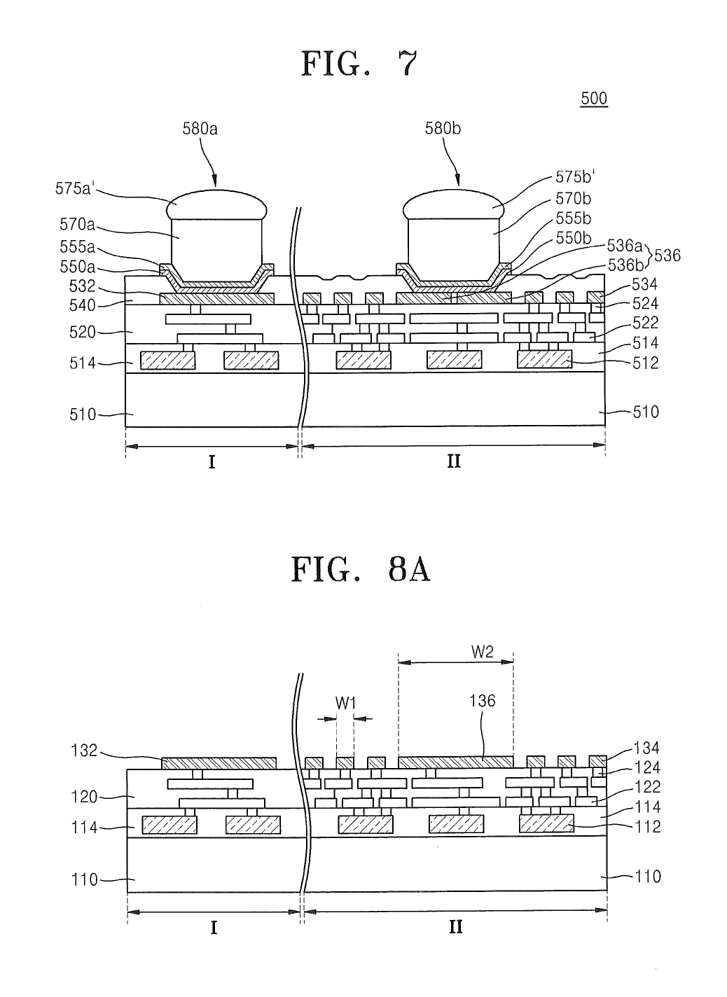

FIG. 4 is a cross-sectional view of a semiconductor device 200 according to various other embodiments described herein. The semiconductor device 200 of FIG. 4 is substantially the same as the semiconductor device 100 described with reference to FIG. 3, except the structure of a first wiring pattern 234 in the semiconductor device 200.

Referring to FIG. 4, integrated circuit units 212 and a first insulating interlayer 214 are provided on a substrate 210, and a second insulating interlayer 220 that covers a plurality of internal wiring patterns 222 and contact plugs 224 is provided on the first insulating interlayer 214.

A pad 232 is provided on the second insulating interlayer 220 in the main solder bump formation region I, and the first wiring pattern 234 is provided on the second insulating interlayer 220 in the dummy solder bump formation region II. The pad 232 may be connected to the integrated circuit units 212 and may be used as an input/output terminal. The first wiring pattern 234 may be arranged in a linear shape having a predetermined width and gap. The first wiring pattern 234 is not provided on a region of the second insulating interlayer 220 on which a dummy solder bump 280b is provided.

A passivation layer 240 that covers an edge portion of the pad 232 and the first wiring pattern 234 is provided on the second insulating interlayer 220. The passivation layer 240 may expose a portion of an upper surface of the pad 232 and may completely cover an upper surface of the first wiring pattern 234. The passivation layer 240 on the first wiring pattern 234 may have an uneven upper surface having step differences, and the passivation layer 240 not on the first wiring pattern 234 may have a flat upper surface without step differences.

A first barrier layer 250a is provided on the exposed portion of the upper surface of the pad 232 and inner surfaces of the passivation layer 240, and a second barrier layer 250b is provided on a portion of the passivation layer 240 on which the dummy solder bump 280b is formed.

First and second seed layers 255a and 255b are provided on the first and second barrier layers 250a and 250b, respectively.

A main solder bump 280a includes a first pillar 270a and a first reflow solder layer 275a′, which are sequentially stacked on the first seed layer 255a.

The dummy solder bump 280b includes a second pillar 270b and a second reflow solder layer 275b′, which are sequentially stacked on the second seed layer 255b. Immediately under the dummy solder bump 280b, the first wiring pattern 234 is not provided and the flat passivation layer 240 is provided without step differences. That is, the dummy solder bump 280b may not overlap with the first wiring pattern 234. The sidewalls of the second pillar 270b may have a vertical profile.

According to the example embodiments, the passivation layer 240 under the dummy solder bump 280b includes less step differences than the passivation layer 240 on which the dummy solder bump 280b is not located and, thus, the sidewalls of the second pillar 270b of the dummy solder bump 280b may be vertical and the dummy solder bump 280b may have a uniform height. Accordingly, the semiconductor device 200 may have a high reliability.

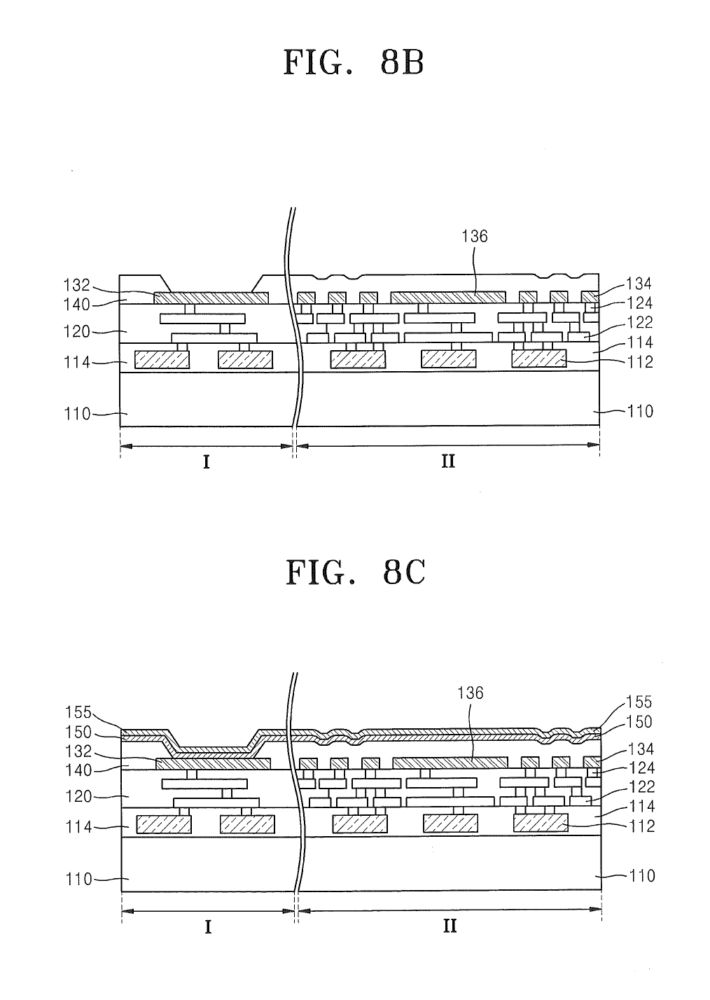

FIG. 5 is a cross-sectional view of a semiconductor device 300 according to various other embodiments described herein. The semiconductor device 300 of FIG. 5 is substantially the same as the semiconductor device 100 described with reference to FIG. 3, except the structures of first and second wiring patterns 334 and 336 in the semiconductor device 300.

Referring to FIG. 5, integrated circuit units 312 and a first insulating interlayer 314 are provided on a substrate 310, and a second insulating interlayer 320 that covers a plurality of internal wiring patterns 322 and contact plugs 324 is provided on the first insulating interlayer 314.

A pad 332 is located on the second insulating interlayer 320 in the main solder bump formation region I, and the first wiring pattern 334 and the second wiring pattern 336 are provided on the second insulating interlayer 320 in the dummy solder bump formation region II. The pad 332 may be connected to the integrated circuit units 312 and may be used as an input/output terminal. The first wiring pattern 334 may be arranged in a linear shape having a predetermined width and gap. The second wiring pattern 336 is located on a region of the second insulating interlayer 320 on which a dummy solder bump 380b is provided. The second wiring pattern 336 may be provided as a plurality of lines having a width greater than that of the first wiring pattern 334. For example, the second wiring pattern 336 may include two wiring lines 336a and 336b are closely spaced apart from each other. The two wiring lines 336a and 336b of the second wiring pattern 336 may be separated by a predetermined gap. The gap between the two wiring lines 336a and 336b may be equal to or smaller than a gap of the first wiring pattern 334.

A passivation layer 340 that covers an edge portion of the pad 332, the first wiring pattern 334, and the second wiring pattern 336 is provided on the second insulating interlayer 320. The passivation layer 340 may expose a portion of an upper surface of the pad 332 and may completely cover upper surfaces of the first wiring pattern 334 and the second wiring pattern 336. The passivation layer 340 on the first wiring pattern 334 may have an uneven upper surface having step differences, and the passivation layer 340 on the second wiring pattern 336 may have a flat upper surface without step differences.

A first barrier layer 350a is provided on the exposed portion of the upper surface of the pad 332 and inner surfaces of the passivation layer 340, and a second barrier layer 350b is provided on the second wiring pattern 336.

First and second seed layers 355a and 355b are provided on the first and second barrier layers 350a and 350b, respectively.

A main solder bump 380a includes a first pillar 370a and a first reflow solder layer 375a′, which are sequentially stacked on the first seed layer 355a.

The dummy solder bump 380b includes a second pillar 370b and a second reflow solder layer 375b′, which are sequentially stacked on the second seed layer 355b. The dummy solder bump 380b is provided on the flat passivation layer 340, above the second wiring pattern 336. A sidewall of the second pillar 370b may have a vertical profile.

According to the example embodiments, the passivation layer 340 under the dummy solder bump 380b includes less step differences than the passivation layer 340 on which the dummy solder bump 380b is not provided and, thus, the sidewalls of the second pillar 370b of the dummy solder bump 380b may be vertical and the dummy solder bump 380b may have a uniform height. Accordingly, the semiconductor device 300 may have a high reliability.

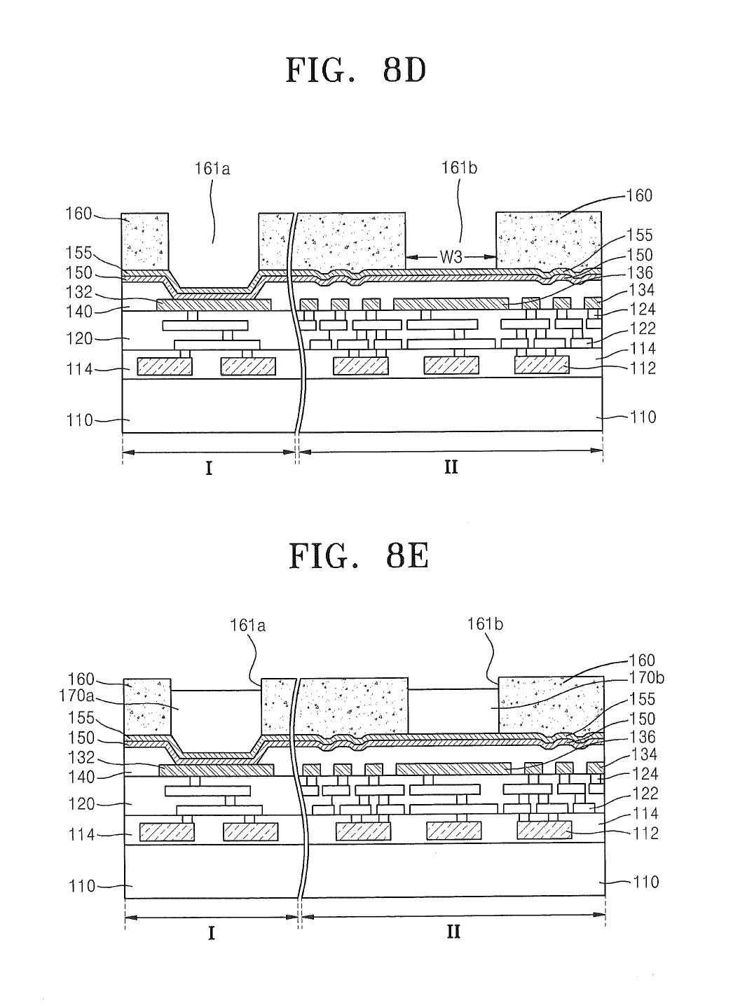

FIG. 6 is a cross-sectional view of a semiconductor device 400 according to various other embodiments described herein. The semiconductor device 400 of FIG. 6 is substantially the same as the semiconductor device 100 described with reference to FIG. 3, except that a passivation layer 440 is not provided under a dummy solder bump 480b in the semiconductor device 400.

Referring to FIG. 6, integrated circuit units 412 and a first insulating interlayer 414 are provided on a substrate 410, and a second insulating interlayer 420 that covers a plurality of internal wiring patterns 422 and contact plugs 424 is provided on the first insulating interlayer 414.

A pad 432 is provided on the second insulating interlayer 420 in the main solder bump formation region I, and a first wiring pattern 434 and a second wiring pattern 436 are located on the second insulating interlayer 420 in the dummy solder bump formation region II. The pad 432 may be connected to the integrated circuit units 412 and may be used as an input/output terminal. The first wiring pattern 434 may have a first width W1 and may be arranged in a plurality of lines separated from each other. The second wiring pattern 436 is provided on a region of the second insulating interlayer 420 on which the dummy solder bump 480b is located. The second wiring pattern 436 is not electrically connected to the integrated circuit units 412. The second wiring pattern 436 may have a second width W2. The second width W2 may be greater than a width of the dummy solder bump 480b. The second width W2 may be greater than the first width W1 of the first wiring pattern 434.

A passivation layer 440 that covers an edge portion of the pad 432, an edge portion of the second wiring pattern 436, and the first wiring pattern 434 is provided on the second insulating interlayer 420. The passivation layer 440 may expose a portion of an upper surface of the pad 432 and a portion of an upper surface of the second wiring pattern 436, and may completely cover an upper surface of the first wiring pattern 434.

A first barrier layer 450a is provided on the exposed portion of the upper surface of the pad 432 and inner surfaces of the passivation layer 440, and a second barrier layer 450b is provided on the exposed portion of the upper surface of the second wiring pattern 436 and inner surfaces of the passivation layer 540.

First and second seed layers 455a and 455b are provided on the first and second barrier layers 450a and 450b, respectively.

A main solder bump 480a includes a first pillar 470a and a first reflow solder layer 475a′, which are sequentially stacked on the first seed layer 455a.

The dummy solder bump 480b includes a second pillar 470b and a second reflow solder layer 475b′, which are sequentially stacked on the second seed layer 455b. The dummy solder bump 480b is provided on the flat second wiring pattern 436. A sidewall of the second pillar 470b may have a vertical profile.

According to the example embodiments, the passivation layer 440 is not provided under the dummy solder bump 480b, and the dummy solder bump 480b is located above the second wiring pattern 436 exposed through the passivation layer 440. The dummy solder bump 480b has a width W3 smaller than the second width W2 of the second wiring pattern 436 formed directly thereunder, and thus, a lower region of the dummy solder bump 480b has small step differences. Accordingly, the sidewalls of the second pillar 470b of the dummy solder bump 480b may be vertically formed and the height of the dummy solder bump 480b may be uniform. Accordingly, the semiconductor device 400 may have a high reliability.

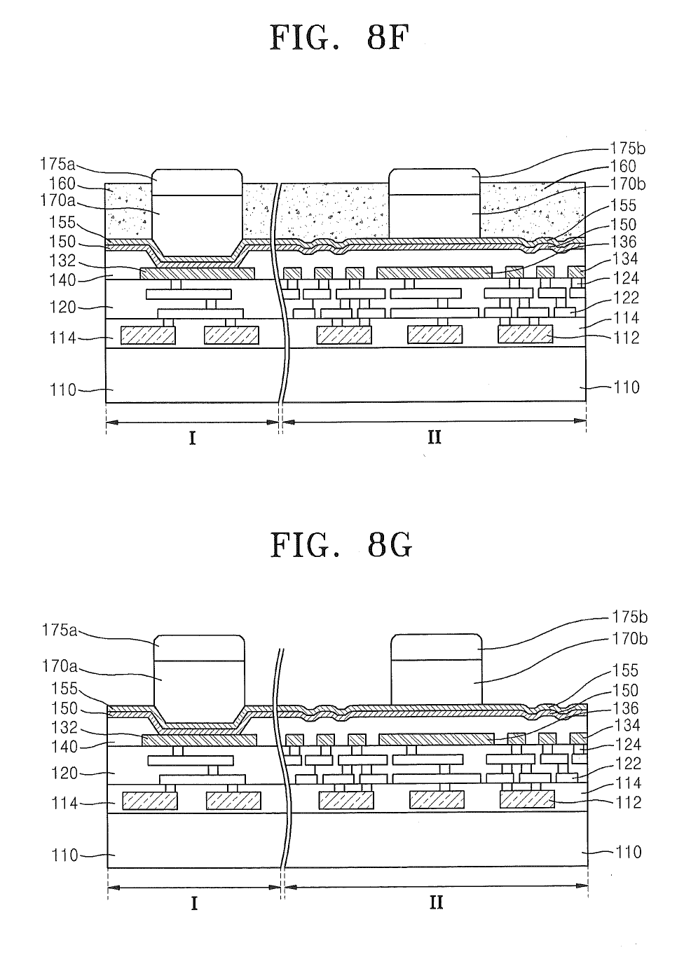

FIG. 7 is a cross-sectional view of a semiconductor device 500 according to various other embodiments described herein. The semiconductor device 500 of FIG. 7 is substantially the same as the semiconductor device 300 described with reference to FIG. 5, except that a passivation layer 540 is not provided under a dummy solder bump 580b.

Referring to FIG. 7, integrated circuit units 512 and a first insulating interlayer 514 are provided on a substrate 510, and a second insulating interlayer 520 that covers a plurality of internal wiring patterns 522 and contact plugs 524 is provided on the first insulating interlayer 514.

A pad 532 is provided on the second insulating interlayer 520 in the main solder bump formation region I, and a first wiring pattern 534 and a second wiring pattern 536 are provided on the second insulating interlayer 520 in the dummy solder bump formation region II. The pad 532 may be connected to the integrated circuit units 512 and may be used as an input/output terminal. The first wiring pattern 534 may be arranged in a linear shape having a predetermined width and gap. The second wiring pattern 536 is provided on a region of the second insulating interlayer 520 on which the dummy solder bump 580b is located. The second wiring pattern 536 may have a plurality of lines having a width greater than that of the first wiring pattern 534. For example, the second wiring pattern 536 may include two wiring lines 536a and 536b separated from each other. The two wiring lines 536a and 536b of the second wiring pattern 536 may be separated by a predetermined gap. The gap between the two wiring lines 536a and 536b may be equal to or smaller than a gap of the first wiring pattern 534.

The passivation layer 540 that covers an edge portion of the pad 532, a portion of the second wiring pattern 536, and the first wiring pattern 534 is provided on the second insulating interlayer 520. The passivation layer 540 may expose a portion of an upper surface of the pad 532 and a portion of an upper surface of the second wiring pattern 536, and may completely cover an upper surface of the first wiring pattern 534.

A first barrier layer 550a is provided on the exposed portion of the upper surface of the pad 532 and inner surfaces of the passivation layer 540, and a second barrier layer 550b is provided on the exposed portion of the upper surface of the second wiring pattern 536 and inner surfaces of the passivation layer 540.

First and second seed layers 555a and 555b are provided on the first and second barrier layers 550a and 550b, respectively.

A main solder bump 580a includes a first pillar 570a and a first reflow solder layer 575a′, which are sequentially stacked on the first seed layer 555a.

The dummy solder bump 580b includes a second pillar 570b and a second reflow solder layer 575W, which are sequentially stacked on the second seed layer 555b. The dummy solder bump 580b is located on the flat second wiring pattern 536. The sidewalls of the second pillar 570b may have a vertical profile.

According to the example embodiments, the passivation layer 540 is not provided under the dummy solder bump 580b, and the dummy solder bump 580b is located above the second wiring pattern 536 exposed through the passivation layer 540. A lower region of the dummy solder bump 580b does not have much step differences, and the sidewalls of the second pillar 570b of the dummy solder bump 580b may be vertically formed. Also, the height of the dummy solder bump 580b may be uniform. Accordingly, the semiconductor device 500 may have a high reliability.

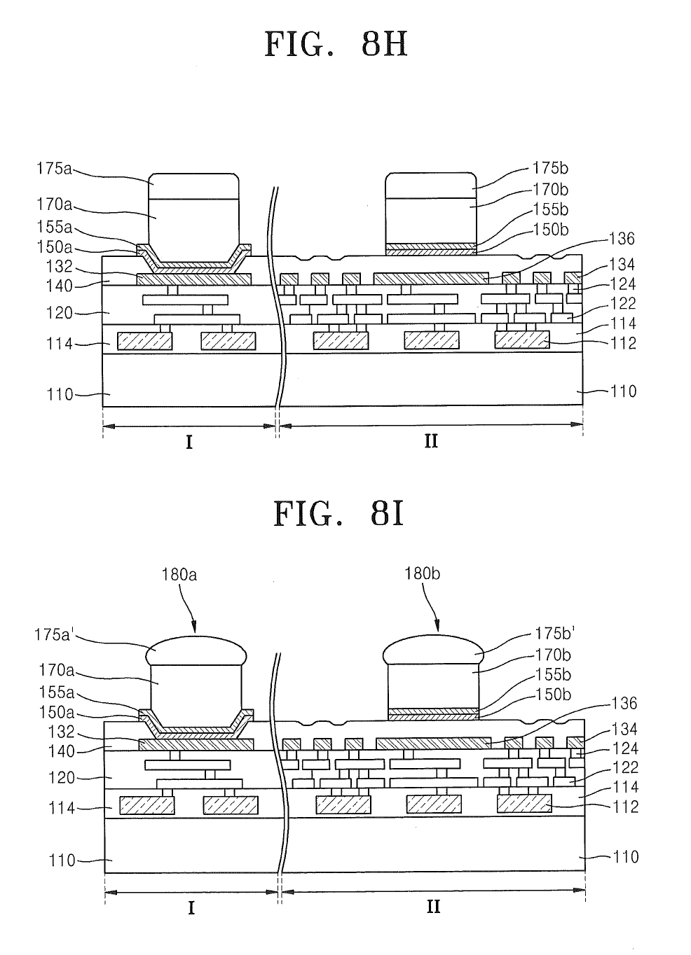

FIGS. 8A through 8I are cross-sectional views for explaining methods of manufacturing the semiconductor device 100, according to various embodiments described herein.

Referring to FIG. 8A, integrated circuit units 112 that include transistors and memory devices are on a substrate 110 which is divided into a main solder bump formation region I and a dummy solder bump formation region II. A first insulating interlayer 114 may further be formed on the substrate 110 to cover the integrated circuit units 112. Internal wiring patterns 122 and contact plugs 124 that are electrically connected to the integrated circuit units 112 may further be formed on the first insulating interlayer 114. A second insulating interlayer 120 that covers the internal wiring patterns 122 and the contact plugs 124 is formed on the first insulating interlayer 114. For example, a plurality of insulating layers (not shown) are formed on the first insulating interlayer 114, and the insulating layers may be formed to cover the multi-layered internal wiring patterns 122 and the contact plugs 124. The insulating layers may be defined as the second insulating interlayer 120.

Pads 132 are formed on the second insulating interlayer 120 in the main solder bump formation region I, and a first wiring pattern 134 and a second wiring pattern 136 are formed on the second insulating interlayer 120 in the dummy solder bump formation region II. For example, after forming a conductive layer (not shown) on the second insulating interlayer 120, the pads 132, the first wiring pattern 134, and the second wiring pattern 136 may be formed by patterning the conductive layer.

The pads 132 may be electrically connected to the internal wiring patterns 122 and the contact plugs 124. The pads 132 may be formed with a large width so that a main solder bump 180a (refer to FIG. 8I) is formed on an upper part of the pads 132 in a subsequent process. For example, the pads 132 may have a width in a range from about a few micrometers to about a few tens of micrometers.

The first wiring pattern 134 may have a predetermined pattern on the second insulating interlayer 120. For example, the first wiring pattern 134 may have a first width W1 and may extend in a direction as separated lines on the second insulating interlayer 120. Also, the first width W1 of the first wiring pattern 134 may be formed smaller than the width of the pads 132.

The second wiring pattern 136 may be formed on a region of the second insulating interlayer 120 on which the dummy solder bump 180b is formed. The second wiring pattern 136 may have a second width W2. The second width W2 may be greater than a third width W3 of a second pillar 170b of the dummy solder bump 180b which is formed on the second wiring pattern 136 in a subsequent process. The second width W2 may be greater than the first width W1 of the first wiring pattern 134. In example embodiments, the second width W2 of the second wiring pattern 136 may be formed similar to the width of the pads 132. For example, the second wiring pattern 136 may be formed to have the second width W2 in a range from about a few to a few tens of micrometers.

Referring to FIG. 8B, an insulating layer (not shown) may be formed on the second insulating interlayer 120 to cover the pad 132, the first wiring pattern 134, and the second wiring pattern 136, and a passivation layer 140 that covers an edge portion of the pad 132, the first wiring pattern 134, and the second wiring pattern 136 is formed by removing a portion of the insulating layer on the pad 132. The passivation layer 140 may be formed of silicon nitride and/or polyimide.

The passivation layer 140 on the first wiring pattern 134 may have an uneven upper surface having step differences. The passivation layer 140 on the second wiring pattern 136 may have a flat upper surface. For example, the first wiring pattern 134 may be formed as a plurality of lines separated by predetermined gaps, which are buried in a process of forming the passivation layer 140. Accordingly, the passivation layer 140 on the lines of the first wiring pattern 134 may be formed higher than the height of the passivation layer 140. Thus, the passivation layer 140 on the first wiring pattern 134 may have an upper surface having step differences. However, the second wiring pattern 136 has a relatively wide width, and thus, the passivation layer 140 on the second wiring pattern 136 may have a relatively flat upper surface.

Referring to FIG. 8C, a barrier layer 150 is formed on the passivation layer 140 and the pad 132. In example embodiments, the barrier layer 150 may comprise Cr, Ni, Ti, TiW and/or a combination of these materials by using a sputtering process, a physical vapor deposition (PVD) process and/or a chemical vapor deposition (CVD) process. In example embodiments, the barrier layer 150 may have a thickness in a range from about 1,000 Å to about 4,000 Å.

A seed layer 155 is formed on the barrier layer 150. In example embodiments, the seed layer 155 may comprise Cr, Ni, Ti, TiW and/or a combination of these materials by using a sputtering process, a PVD process and/or a CVD process. In example embodiments, the seed layer 155 may have a thickness in a range from about 1,000 Å to about 4,000 Å.

The barrier layer 150 may reduce or prevent materials that constitute the seed layer 155 from diffusing downwards. Also, the barrier layer 150 may function as an adhesive layer for the seed layer 155 to adhere to the pad 132 or the passivation layer 140.

Referring to FIG. 8D, a photoresist pattern 160 is formed on the seed layer 155. A first opening 161a and a second opening 161b that expose portions of the seed layer 155 may be formed in the photoresist pattern 160. The first opening 161a exposes a portion of the seed layer 155 on the pad 132. The second opening 161b may expose a portion of the seed layer 155 on the second wiring pattern 136. The first and second openings 161a and 161b may be formed to have a third width W3. Alternatively, the first and second openings 161a and 161b may be formed to have different widths.

The first and second openings 161a and 161b may each be formed to substantially have a circular cross-section, an oval cross-section, or a rectangular cross-section in a vertical direction to an upper surface of the substrate 110. When the pads 132 are formed in plural, the first opening 161 a may be formed in plural to correspond to the number of the pads 132. The second opening 161b may be formed in plural regardless of the number of the pads 132. In a subsequent process, a main solder bump 180a (refer to FIG. 8I) is formed in each of the first openings 161a, and a dummy solder bump 180b (refer to FIG. 8I) is formed in each of the second openings 161b.

The second opening 161b is formed in the passivation layer 140 below which the second wiring pattern 136 is formed. When the second opening 161b is formed on the first wiring pattern 134, since the first wiring pattern 134 is disposed in plural with a width and gap smaller than that of the second opening 161b, the passivation layer 140 on the first wiring pattern 134 may have step differences. Accordingly, in a photoresist process for patterning the second opening 161b, the patterning process may not be easy due to the step differences of the passivation layer 140 therebelow, and sidewalls of the second opening 161b may not have a vertical profile. For example, a width of the second opening 161b that is formed on an upper part of the photoresist pattern 160 may be formed smaller than a width of the second opening 161b that is formed on a lower part of the photoresist pattern 160. Also, a recess or a convex portion may be formed on central sidewalls of the second opening 161b. In this way, if the vertical profile of the second opening 161b is not uniform, a volume of the second opening 161b may be non-uniformly formed with some deviations. Also, in a subsequent plating process for filling an inner side of the second opening 161b, a plating height may be non-uniform with some deviations, and the height of the dummy solder bump 180b may be too high or too low. However, when the second opening 161b is formed on the second wiring pattern 136, the passivation layer 140 is formed flat, and thus, the inner surfaces of the second opening 161b may have a high vertical profile in a photoresist process and the second opening 161b may have a uniform width across the entire height.

Referring to FIG. 8E, a first pillar 170a and the second pillar 170b are formed on the seed layer 155 that is exposed in the first opening 161a and the second opening 161b formed in the photoresist pattern 160, respectively.

The first pillar 170a and the second pillar 170b may be formed by using an electroplating process or an electroless plating process. For example, after placing the substrate 110, on which the photoresist pattern 160 is formed, in a bath, an electroplating may be performed to grow the first pillar 170a and the second pillar 170b from the seed layer 155. In example embodiments, the first pillar 170a and the second pillar 170b may comprise Cu, Ni, Au and/or an alloy of these materials, or may be a multi-layer structure of metals comprising Cu, Ni and/or Au.

The first pillar 170a and the second pillar 170b may be formed to partly, not completely, fill inner surfaces of the first opening 161a and the second opening 161b.

Referring to FIG. 8F, a first solder layer 175a and a second solder layer 175b are formed on the first pillar 170a and the second pillar 170b, respectively. The first solder layer 175a and the second solder layer 175b may be formed to protrude from an uppermost surface of the photoresist pattern 160. In other embodiments, the first solder layer 175a and the second solder layer 175b may be formed not to protrude from the uppermost surface of the photoresist pattern 160 or may be formed lower than the uppermost surface of the photoresist pattern 160.

The first solder layer 175a and the second solder layer 175b may be formed by using an electroplating process. For example, in order to form the first solder layer 175a and the second solder layer 175b, the substrate 110 is placed in another bath from the bath where an electroplating is performed for forming the first pillar 170a and the second pillar 170b, and afterwards, an electroplating process may be performed. In example embodiments, the first solder layer 175a and the second solder layer 175b may be an alloy of Sn and/or Ag, and, if necessary, Cu, Pd, Bi and/or Sb may be included in the alloy.

Referring to FIG. 8G, the photoresist pattern 160 of FIG. 8F is removed. The photoresist pattern 160 may be removed by using a strip process or an ashing process.

Accordingly, the first pillar 170a and the first solder layer 175a may be separated from the second pillar 170b and the second solder layer 175b.

Referring to FIG. 8H, the exposed seed layer 155 and the barrier layer 150 are sequentially removed, and thus, the first seed layer 155a and the first barrier layer 150a remain under the first pillar 170a and the first solder layer 175a, and the second seed layer 155b and the second barrier layer 150b remain under the second pillar 170b and the second solder layer 175b. The seed layer 155 and the barrier layer 150 may be removed by using a wet etching process or a dry etching process.

A process of removing a natural oxide layer (not shown) formed on surfaces of the first and second pillars 170a and 170b and the first and second solder layers 175a and 175b may further be performed. For example, when a liquid flux is coated on the surfaces of the first and second pillars 170a and 170b and the first and second solder layers 175a and 175b, the natural oxide layer may be removed therefrom and wettability in a subsequent process may be increased. Optionally, the natural oxide layer may be removed by using a fluxless process in which a gas such as a formic acid gas and/or an N2 gas is injected.

Referring to FIG. 8I, a reflow process may be performed on the substrate 110. Accordingly, the first solder layer 175a and the second solder layer 175b melt, and thus, a first reflow solder layer 175a′ and a second reflow solder layer 175b′ may be formed. The reflow process may be performed at a temperature in a range from about 200° C. to about 300° C.

In the reflow process, the first reflow solder layer 175a′ and the second reflow solder layer 175b′ may be reshaped into a hemispherical shape having a relatively small surface area due to surface tension.

Accordingly, a main solder bump 180a that includes the first pillar 170a and the first reflow solder layer 175a′ is formed. The first reflow solder layer 175a′ of the main solder bump 180a may be formed to partly protrude with respect to sidewalls of the first pillar 170a. Also, an inter-metallic compound (IMC) (not shown) may be formed at an interface between the first reflow solder layer 175a′ and the first pillar 170a. The main solder bump 180a may be formed to have a height and width in a range from about a few micrometers to about a few tens of micrometers.

A dummy solder bump 180b that includes the second pillar 170b and the second reflow solder layer 175b′ may further be formed. The dummy solder bump 180b may be formed in a shape similar to that of the main solder bump 180a.

According to various embodiments described herein, the passivation layer 140 on the second wiring pattern 136 is formed flat, and thus, in a photoresist process for forming the second opening 161b on the second wiring pattern 136, inner surfaces of the second opening 161b may be formed to have a uniform vertical profile. Accordingly, the second pillar 170b and the second reflow solder layer 175b′ which are formed in the second opening 161b may be formed to have a uniform height. Therefore, the semiconductor device 100 may have a high reliability.

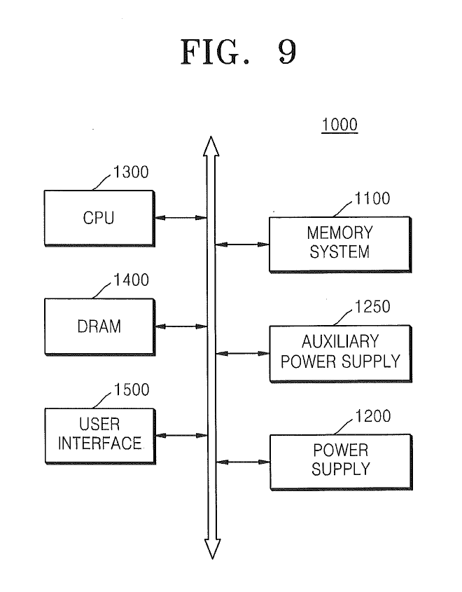

FIG. 9 is a block diagram illustrating an example of an electronic device including a semiconductor device according to various embodiments described herein. An electronic device 1000 may be embodied by a personal computer PC or a portable electronic device such as a notebook computer, a cell phone, a personal digital assistant (PDA) and a camera.

Referring to FIG. 9, the electronic device 1000 includes a memory system 1100, a power supply 1200, an auxiliary power supply 1250, a central processing unit 1300, a DRAM 1400 and a user interface 1500. The memory system 1100 may be embodied by a semiconductor device according to any of the embodiments described herein. The CPU 1300, DRAM 1400 and/or user interface 1500 also may be embodied by a semiconductor device according to any of the embodiments described herein.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

While the inventive concepts have been particularly shown and described with reference to various embodiments thereof, it will be understood that various changes in form and details may be made therein without departing from the spirit and scope of the following claims.

What is claimed is:

1. A semiconductor device comprising:
a substrate;
a plurality of integrated circuit units on the substrate;
a plurality of main solder bumps on the substrate, the plurality of main solder bumps being electrically connected to the integrated circuit units; and
a plurality of dummy solder bumps on the substrate, the plurality of dummy solder bumps not being electrically connected to the integrated circuit units, the dummy solder bumps being narrower than wiring patterns directly therebelow.

2. The semiconductor device of claim 1, wherein bottom surfaces of the dummy solder bumps are flat.

3. The semiconductor device of claim 1, wherein each of the dummy solder bumps comprises a pillar adjacent the substrate and a reflow solder layer remote from the substrate, and sidewalls of the pillar have a vertical profile.

4. The semiconductor device of claim 1, wherein the dummy solder bumps vertically overlap with the wiring patterns.

5. The semiconductor device of claim 1, further comprising:
an insulating interlayer on the integrated circuit units; and
a plurality of pads on the insulating interlayer,
wherein the wiring patterns are in the insulating interlayer.

6. The semiconductor device of claim 5, further comprising a passivation layer on the insulating interlayer to cover a portion of the pads and the wiring patterns.

7. The semiconductor device of claim 6, wherein the passivation layer completely covers the wiring patterns and the dummy solder bumps are on the passivation layer.

8. The semiconductor device of claim 7, wherein portions of an outer surface of the passivation layer on which the dummy solder bumps are located are flat.

9. The semiconductor device of claim 5, wherein the passivation layer exposes a portion of the pads and a portion of the wiring patterns, the main solder bumps are on the exposed portion of the pads, and the dummy solder bumps are on the exposed portion of the wiring patterns.

10. The semiconductor device of claim 9, wherein outer surfaces of the wiring patterns on which the dummy solder bumps are located are flat.

11. The semiconductor device of claim 5, wherein the wiring patterns comprise two closely spaced apart wiring lines.

12. A semiconductor device comprising:
a substrate;
a plurality of integrated circuit units on the substrate;
an insulating interlayer on the integrated circuit units on the substrate;
a plurality of wiring patterns and pads on the insulating interlayer that are electrically connected to the integrated circuit units;
a passivation layer on the wiring patterns and the pads on the insulating interlayer;
a plurality of main solder bumps that are electrically connected to the integrated circuit units through the pads; and
a plurality of dummy solder bumps on a portion of the passivation layer immediately below which the wiring patterns are not present.

13. The semiconductor device of claim 12, wherein bottom surfaces of the dummy solder bumps are flat.

14. The semiconductor device of claim 12, wherein sidewalls of the dummy solder bumps have a vertical profile.

15. The semiconductor device of claim 12, wherein a portion of the passivation layer below which the dummy solder bumps are located is more planar than a portion of the passivation layer below which the wiring patterns are located.

16. A semiconductor device comprising:
a substrate;
a plurality of semiconductor integrated circuit units on the substrate;
a plurality of main solder bumps on the semiconductor integrated circuit units, remote from the substrate, that are electrically connected to circuits in the semiconductor integrated circuit units; and
a plurality of dummy solder bumps on the semiconductor integrated circuit units, remote from the substrate, that are mechanically connected to the semiconductor integrated circuit units but are not electrically connected to the circuits in the semiconductor integrated circuit units, a respective dummy solder bump having a floor that is adjacent the semiconductor integrated circuit units and a sidewall that meets the floor at a right angle.

17. The semiconductor device of claim 16 further comprising a wiring pattern between the semiconductor integrated circuit units and the main and dummy solder bumps, wherein the floor is narrower than the wiring pattern that is adjacent thereto.

18. The semiconductor device of claim 16 wherein the sidewall defines an enclosed area and the floor is flat throughout the enclosed area.

19. The semiconductor device of claim 16 wherein the substrate includes a plurality of pads thereon that are electrically connected to the plurality of main solder bumps, and wherein the dummy solder bumps are not electrically connected to a pad on the substrate.

20. The semiconductor device of claim 19 further comprising a passivation layer on the substrate that includes apertures therein that expose the plurality of pads and that has a flat outer surface adjacent the dummy solder bumps.
